(19) United States
(12) Patent Application Publication
(10) Pub. No.: US 2012/0014043 A1
(43) Pub. Date: Jan. 19, 2012

(54) PORTABLE ELECTRONIC DEVICE WITH PENDANT ATTACHMENT SYSTEM

(75) Inventors: MIN DONG, Shenzhen (CN); KUAN-HUNG CHEN, Shindian (TW); YAO WANG, Shenzhen (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/894,285

(22) Filed: Sep. 30, 2010

(30) Foreign Application Priority Data
Jul. 16, 2010 (CN) 201010228999.7

(51) Int. Cl. H05K 7/00

(52) U.S. Cl. 361/679.01

(57) ABSTRACT

A portable electronic device includes a housing including a protrusion and a passage extending to the protrusion; an attachment element wrapping on the protrusion and passing through the passage to extend outward from the housing; and a stylus received in the housing to cover the passage and prevent the attachment element from escaping the passage.

The present application is related to co-pending U.S. patent application Ser. No. ______ (Attorney Docket No.US34678), entitled “PORTABLE ELECTRONIC DEVICE WITH PENDANT ATTACHMENT SYSTEM”, by Dong et al. This application has the same assignee as the present application and has been concurrently filed herewith. The above-identified applications are incorporated herein by reference.

### BACKGROUND

1. Technical Field

The exemplary disclosure generally relates to portable electronic devices, particularly to portable electronic devices with a pendant attachment system.

2. Description of Related Art

Mobile phone users often attach decorative pendants to their phones. The pendants generally hang from an attachment element, such as a string or chain looped through a dedicated hole or ligament of the mobile phone. However, it is difficult to thread the attachment element through the hole to attach the pendants as the hole is usually small.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary portable electronic device with a pendant attachment system. Moreover, in the drawings like reference numerals designate corresponding parts throughout the several views. Wherever possible, the same reference numbers are used throughout the drawings to refer to the same or like elements of an embodiment.

FIG. 1 is an exploded view of an exemplary embodiment of portable electronic device including a pendant attachment system provided by a housing and stylus.

FIG. 2 is an enlarged view of the stylus from another aspect.

FIG. 3 is a partially enlarged view of an attachment element fixed to the housing.

FIG. 4 is an assembled view of the portable electronic device shown in FIG. 1.

### DETAILED DESCRIPTION

In this exemplary embodiment, the device is an electronic device such as a mobile telephone but any device to which a pendant can be attached is applicable. Accordingly, any reference herein to the mobile telephone should also be considered to apply equally to other portable devices.

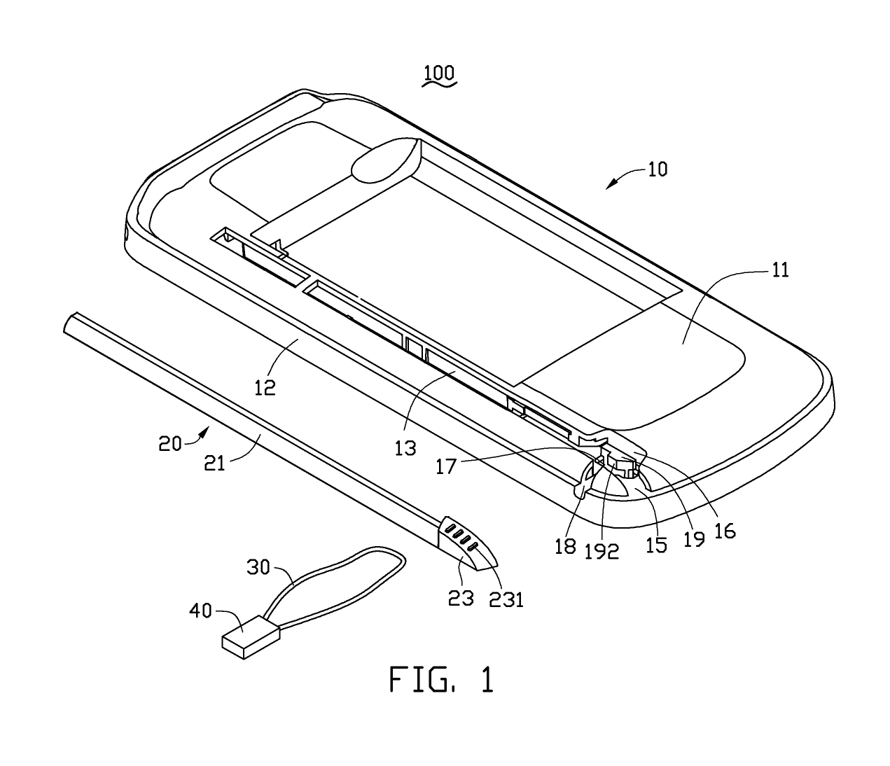

Referring to FIG. 1, the exemplary device 100 includes a housing 10, a stylus 20 and an attachment element 30 of a pendant 40. The housing 10 includes a surface 11, a sidewall 12 connecting to the surface 11, a receptacle 13, an opening 15, a slot 16, a receiving groove 17, a passage 18 and a protrusion 19. The receptacle 13 is recessed from the surface 11 and located near the sidewall 12 to seat the stylus 20. The opening 15 is defined in an end of the housing 10 and communicates with the receptacle 13. The stylus 20 is inserted in the receptacle 13 by the opening 15. The slot 16 is defined at one side of the receptacle 13 and communicates with the receptacle 13. The receiving groove 17 is defined in a bottom 162 of the slot 16 to seat the attachment element 30. The passage 18 is defined in the sidewall 12 opposite to the slot 16 and communicating with the receptacle 13 and the receiving groove 17. The passage 18 allows passage of attachment element 30 through the sidewall 12 and extension thereof outward from the housing 10. The protrusion 19 is located in the receiving groove 17, and the attachment element 30 wraps on the protrusion 19 when the attachment element 30 is located in the receiving groove 17. The protrusion 19 includes two latching portions 191 respectively protruding from opposite sides thereof to maintain the attachment element 30 in the receiving groove 17. The housing 10 further includes a hook 192 protruding from the protrusion 19 to retain the stylus 20 in the receptacle 13.

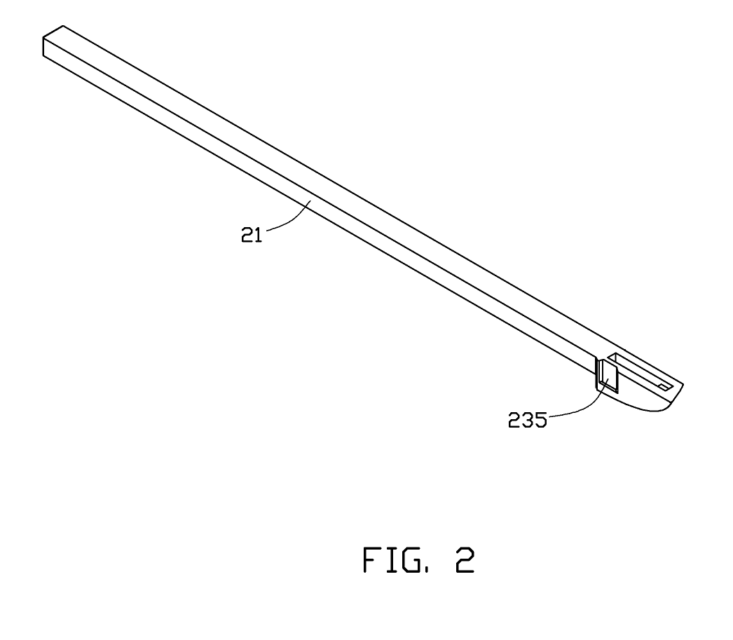

Referring to FIG. 2, the stylus 20 includes a stylus body 21 and a stylus head 23 protruding from the stylus body 21. The stylus 20 further includes a number of ribs 231 protruding from the stylus head 23 facilitating removal of stylus 20 from the receptacle 13, and a latching groove 235 defined in a side of the stylus head 23 facing the protrusion 19 receiving the hook 192 and retaining stylus 20 in the receptacle 13.

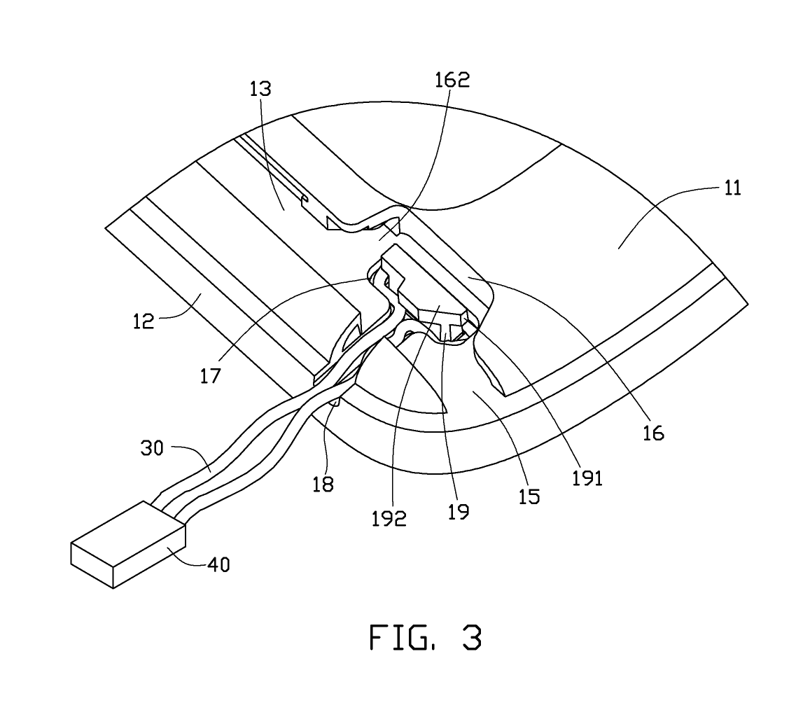

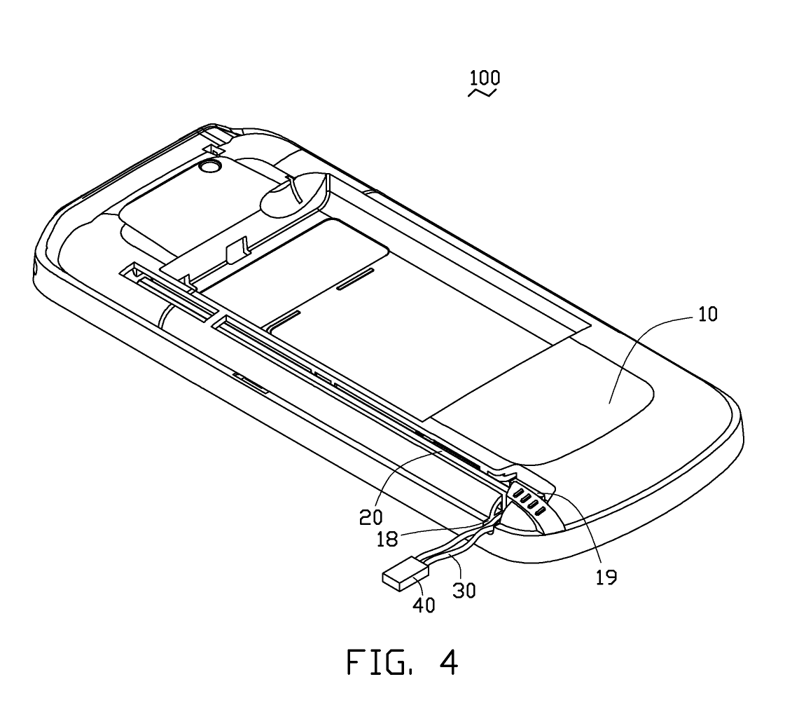

Referring to FIGS. 3 and 4, in use, the attachment element 30 is partially received in the receiving groove 17 and wraps around the protrusion 19, and the remainder of the attachment element 30 extends outward from the housing 10 from the passage 18. The stylus 20 is then received in the receptacle 13 from the opening 15 until the hook 192 is received in the latching groove 235. At this time, the stylus 20 covers the passage 18 to retain the attachment element 30 in the passage 18. To remove the attachment element 30 from the device 100, the stylus 20 is withdrawn from the receptacle 13 with the hook 192 releasing the latching groove 235, such as by removal of the ribs 231. With this motion, the attachment element 30 can be easily removed from the passage 18 and the receiving groove 17.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A portable electronic device, comprising:
a housing including a protrusion and a passage extending to the protrusion;
a attachment element wrapping around the protrusion and passing through the passage to extend outward from the housing; and
a stylus releasably received in the housing, covering a portion of the passage.

2. The portable electronic device as claimed in claim 1, wherein the housing defines a receiving groove seating the attachment element; wherein the protrusion is located in the receiving groove.

3. The portable electronic device as claimed in claim 2, wherein the passage communicates with the receiving groove.

4. The portable electronic device as claimed in claim 2, wherein two latching portions protrude from the protrusion.

5. The portable electronic device as claimed in claim 4, wherein the housing further defines a receptacle to seat the stylus and a slot communicating with the receptacle;
wherein the receiving groove is defined in a bottom of the slot.

6. The portable electronic device as claimed in claim 5, wherein the protrusion comprises a hook protruding therefrom; and the stylus defines a latching groove therein releasably receiving the hook.

7. A portable electronic device, comprising:
a housing including a receptacle, a receiving groove, a passage and a protrusion, wherein the receiving groove and the passage are respectively located at opposite sides of the receptacle, the protrusion is located in the receiving grooves;
an attachment element partially wrapping around the protrusion and located in the receiving groove, the remainder of the attachment element passing through the passage to extend outward from the housing; and
a stylus releasably received in the receptacle covering a portion of the passage.

8. The portable electronic device as claimed in claim 7, wherein two latching portions protrude from the protrusion.

9. The portable electronic device as claimed in claim 7, wherein the housing further defines a slot at one side of the receptacle and communicating with the receptacle; wherein the receiving groove is defined in a bottom of the slot.

10. The portable electronic device as claimed in claim 7, wherein the protrusion comprises a hook protruding therefrom; and the stylus defines a latching groove therein receiving the hook.

11. A portable electronic device, comprising:
a housing including a receptacle defined in a surface thereof, a protrusion and a passage defined through a sidewall of the housing;
a attachment element wrapping around the protrusion and passing through the passage to extend outward from the housing; and
a stylus releasably received in the receptacle locking the attachment element in the passage.

12. The portable electronic device as claimed in claim 11, wherein the housing defines a receiving groove seating the attachment element; wherein the protrusion is located in the receiving groove.

13. The portable electronic device as claimed in claim 12, wherein two latching portions protrude from the protrusion.

14. The portable electronic device as claimed in claim 12, wherein the housing further defines a slot at one side of the receptacle and communicating with the receptacle; wherein the receiving groove is defined in a bottom of the slot.

15. The portable electronic device as claimed in claim 11, wherein the protrusion comprises a hook protruding therefrom; and the stylus defines a latching groove therein receiving the hook.
